(19) United States
(12) Patent Application Publication
(10) Pub. No.: US 2009/0008540 A1
(43) Pub. Date: Jan. 8, 2009

(54) Camera device and electronic device including the same

(75) Inventor: Yoshinori Tanida, Hiroshima (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/217,400

(22) Filed: Jul. 3, 2008

(30) Foreign Application Priority Data
Jul. 4, 2007 (JP) 176703/2007

(51) Int. Cl. H01L 27/14

(52) U.S. Cl. 250/239; 257/E27.13

(57) ABSTRACT

In a camera device of the present invention, a camera module 2 is mounted on a substrate 1 provided in the camera device by use of contact pins 3 for connecting first terminals provided on a backside of the camera module 2 to second terminals provided on the substrate 1. The contact pins 3 have first and second ends, and the first ends are soldered to ones of the first and second terminals and the second ends have contact with the other ones of the first and second terminals, respectively, so that the camera module 2 is electrically connected to the substrate 1, and the contact pins 3 are provided independently. This decreases restrictions on mounting the camera module 2 on the substrate 1, and also makes it possible to provide a camera device, in which the camera module 2 can be easily mounted on the substrate 1.

This Nonprovisional application claims priority under 35 U.S.C. §119(a) on Patent Application No. 176703/2007 filed in Japan on Jul. 4, 2007, the entire contents of which are hereby incorporated by reference.

### FIELD OF THE INVENTION

The present invention relates to a camera device in which a camera module is mounted on a substrate via contact pins, and an electronic device including the camera device.

### BACKGROUND OF THE INVENTION

A camera module including a lens and a solid-state sensing device is provided in a camera device such as a mobile phone or a digital still camera. The camera module is provided in the camera device such that the camera module is mounted on a substrate such as a connection substrate (a printed circuit board) or a motherboard provided in the camera device. Usually, the camera module is mounted on the substrate by soldering.

However, the camera module includes heat-sensitive optical components such as a lens and an infrared cut filter. Therefore, if the camera module is mounted on the substrate by soldering under a reflow condition that is generally used for mounting electronic components such as a resistor and a capacitor by soldering, the optical components cannot resist heat. From this reason, for the purpose of mounting a camera module on a substrate by soldering, one of the following two methods, for example, is used.

In a first method, a camera module is mounted on a substrate in such a manner that. (i) a camera module without a lens is mounted on a substrate by reflow, and (ii) a lens is fit in the camera module. In the first method, the lens is fit in the camera module after the reflow process. As such, even under the usual reflow condition, optical components such as a lens are not affected by heat.

In a second method, a camera module is mounted on a substrate in such a manner that (i) the camera module is placed on the substrate, and (ii) a solder joint section is locally heated. In the second method, only the solder joint section is locally heated, so that optical components such as a lens are not affected by heat. As such, a camera module having a lens can be mounted on a substrate.

However, the first method requires additional production processes because a lens is fit in the camera module after the reflow process. On this account, practically, it is difficult for a user to carry out the first method. Moreover, in a case where a camera module is transported without a lens, dust may come into the camera module. From this reason, practically, a camera module is required to be dealt with, for sale, in a state where a lens is fit in the camera module that is mounted on a substrate.

On the other hand, the second method requires a special process and a special device (special-purpose device) for locally heating a solder joint section. In addition, in the second method, it is difficult to simultaneously heat solder joint sections of a plurality of camera modules. Therefore, it is necessary that each of the camera modules be respectively mounted. Moreover, because the camera module is held down during the mounting process, there may occur cases where the camera module is not placed at a right position on a substrate.

From these reasons, in either of the methods, production efficiency is very low. Furthermore, in such mounting processes by soldering, it is necessary to set conditions such as an amount of solder (thickness of preparatory solder), heating period, and cooling down period depending on models of camera modules, and this requires long time.

In this regard, Patent Document 1 discloses a method of mounting a camera module on a substrate, which improves operation efficiency (production efficiency) and aims at an improvement in mounting accuracy. FIG. 9 is a view illustrating a mounting method of Patent Document 1. As illustrated in FIG. 9, in Patent Document 1, a camera module is mounted on a substrate by use of a coupler (a housing (frame)). More specifically, in Patent Document 1, a camera module 111 is mounted on a printed circuit board 112 in such a manner that a coupler 114 is mounted, via a solder 115, on a terminal 113 provided on the printed circuit board 112, and the camera module 111 is embedded therein.

However, in the case where the camera module 111 is mounted on the printed circuit board 112 by use of the coupler 114 as disclosed in Patent Document 1, an extra component member, i.e., the coupler 114, is required. In addition, a width of the camera module 111 becomes wider due to the coupler 114. This causes a problem in which it is difficult to apply such a camera module to camera devices that have been further downsized and thinner.

More particularly, as illustrated in FIG. 9, it is necessary that a plurality of terminals 113a be provided in a protruding condition so that the camera module 111 is embedded in the coupler 114. For this reason, it is necessary that terminals 113b of the camera module 111 be provided such that each of the terminals 113b corresponds to each of the terminals 113a of the coupler 114. This means that the terminals 113b are required to be provided on a side surface of the camera module 111.

However, in this case, when the camera module 111 is embedded in the coupler 114, the camera module 111 is enclosed by the coupler 114. As such, a width of the camera module 111 becomes larger due to the terminals 113a and the coupler 114. Thus, the size of the camera module 111 is enlarged.

A camera device such as a mobile phone in which a camera module is incorporated has been more downsized and thinner rapidly. On the other hand, it is necessary that, in such a camera device, a camera module be placed (mounted) on a particular position in view of a design or the like. However, as in the case of Patent Document 1, if the width of the camera module 111 is wider, a position where the camera module 111 is placed in the camera device is largely limited. This makes it difficult to mount a camera module on an intended position on a substrate.

[Patent Document 1]

Japanese Unexamined Patent Publication, Tokukai, No. 2004-63787 (published on Feb. 26, 2004)

### SUMMARY OF THE INVENTION

The present invention is accomplished in view of the above problems. An object of the present invention is to provide a camera device, which decreases restrictions on mounting a camera module on a substrate and allows the camera module to be easily mounted on the substrate.

In order to achieve the object, a camera device of the present invention, in which a camera module is mounted on a substrate, includes a plurality of contact pins for connecting a plurality of first terminals provided on a backside of the camera module to a plurality of second terminals provided on the substrate, respectively, the contact pins having first and second ends, the first ends being soldered to ones of the first and second terminals and the second ends having contact with the other ones of the first terminals and the second terminals, respectively, so that the camera module is electrically connected to the substrate, and the contact pins being provided independently.

In the arrangement, the camera device includes contact pins for electrically connecting the camera module to the substrate. First ends of the contact pins are connected to the first terminals and second ends of the contact pins are connected to the second terminals, respectively. When the first terminals are provided on the backside of the camera module as such, even if the camera module is connected to the substrate via the contact pins, a width of the camera module is not required to be wider than its original width. This makes it possible to decrease restrictions on mounting a camera module on a substrate.

Moreover, in the arrangement, the contact pins are provided independently. In other words, the contact pins are exposed, and are not arranged such that a part of or all the plurality of contact pins is/are fixed together as a unit. Accordingly, in the arrangement, unlike Patent Document 1, a coupler is not necessary, and further it is not necessary that terminals be fixed to the coupler. This makes it possible to realize a downsized and thinner camera device.

Furthermore, in the arrangement, the contact pins are soldered to only ones of the first and second terminals. That is, the contact pins are soldered to one of the camera module and the substrate. This makes it possible to easily mount a camera module on a substrate. It is also possible to easily replace the camera module or the substrate that is not soldered to the contact pins.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross sectional view of a camera device of the present invention, and illustrates how a camera module is mounted on a substrate.

FIG. 2 is a top view of the camera device of the present invention, and illustrates how the camera device is mounted on the substrate.

FIG. 3 is a cross sectional view of the camera device of the present invention, and partially illustrates how the substrate is connected to the camera module via contact pins.

FIG. 4 is a top view of the substrate of the camera device of the present invention, on which substrate the camera module is not mounted yet.

FIG. 5 is a cross sectional view illustrating an engaging structure in which a first terminal of the camera module engages with the contact pin, in the camera device of the present invention.

FIG. 6 is a cross sectional view illustrating an arrangement in which the camera module is fixed on the substrate by use of a case in which the camera module is placed, in the camera device of the present invention.

FIG. 7 is a cross sectional view illustrating an arrangement in which the camera module is fixed on the substrate by an adhesive section, in the camera device of the present invention.

FIG. 8 is a top view of the arrangement of FIG. 7.

FIG. 9 illustrates a method of mounting a camera module on a substrate in a camera device of Patent Document 1.

### DESCRIPTION OF THE EMBODIMENTS

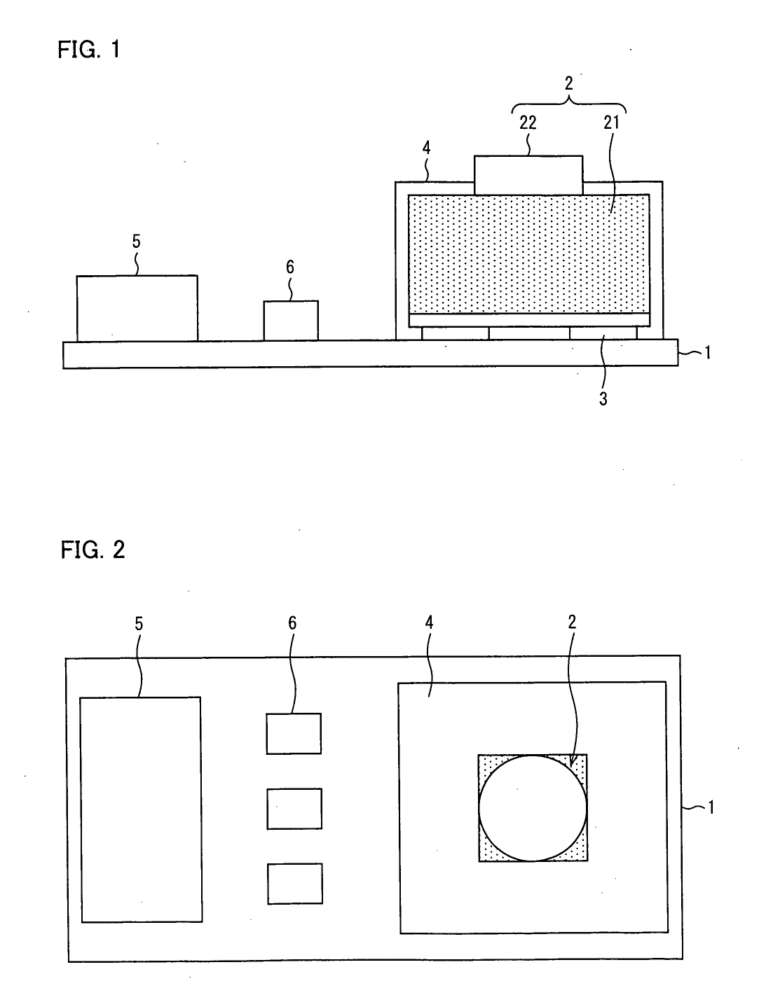

One embodiment of the present invention is described below with reference to FIGS.1 through 8.

In a camera device of the present invention, a camera module is electrically connected to a substrate (on which the camera module is to be mounted) via a plurality of contact pins that are provided independently. This decreases restrictions on mounting a camera module on a substrate and allows a camera module to be easily mounted on a substrate.

The camera device of the present invention can be preferably applied to various photographable electronic devices such as a mobile phone with a camera, a digital still camera, and a security camera. In the present embodiment, the following explanation deals with a mobile phone device with a camera as the camera device.

FIG. 1 is a cross sectional view of a mobile phone device with a camera in accordance with an embodiment of the present invention, and illustrates how a camera module is mounted on a substrate. FIG. 2 is a top view of the arrangement in FIG. 1.

As illustrated in FIGS. 1 and 2, in the mobile phone device with a camera of the present embodiment, a camera module 2 for capturing image is mounted on a substrate 1 that is provided in the mobile phone device. An appearance of the mobile phone device with a camera is not described here because the appearance is the same as that of a well-known mobile phone device.

The substrate 1 is provided in a mobile phone device with a camera, and the camera module 2 is mounted thereon. The substrate 1 is, for example, a motherboard, or a connection substrate of the mobile phone device with a camera. In the mobile phone device with a camera, in order that the camera module 2 is placed at a particular position, a flexible printed circuit board (FPC) is often used as such the substrate 1. If a FPC is used as the substrate 1, then it is possible to place the substrate 1 at any position in the mobile phone device with a camera.

In addition to the camera module 2, (i) an electronic component 5 such as a resistor and a capacitor, and (ii) a connector 6 for transmitting to other member image data captured by the camera module 2 are also mounted on the substrate 1.

The camera module 2 is constituted by an image-capturing section 21 and a lens section 22. The image-capturing section 21 (not illustrated) includes: a solid-state image sensing device (for example, a CCD sensor or a CMOS sensor) for converting external scene information (picture) into an electronic signal; an IR cut filter for cutting an infrared radiation incident on the solid-state image sensing device; a DSP for processing a signal supplied from the solid-state image sensing device; DSP peripheral components and the like. On the other hand, the lens section 22 includes a lens for building up a picture on the solid-state image sensing device. In the present embodiment, the camera module 2 is placed in a case 4, thereby fixing the camera module 2 on the substrate 1. The case 4 will be described later.

The camera module 2 is mounted on the substrate 1 via contact pins 3. In other words, the substrate 1 is electrically connected to the camera module 2 via the contact pins 3.

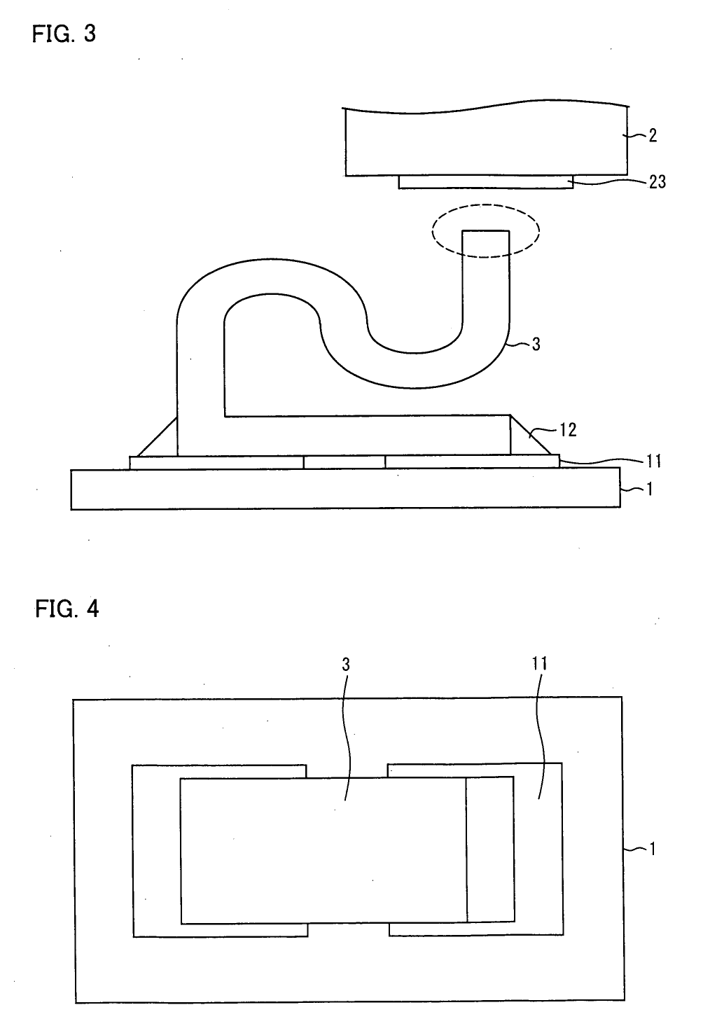

FIG. 3 is a cross sectional view partially illustrating how the substrate 1 is connected to the camera module 2 via the contact pins 3, in the mobile phone device with a camera of the present embodiment. FIG. 4 is a top view of the substrate 1 on which the camera module 2 is not mounted yet, in the arrangement of FIG. 3.

While a plurality of first terminals 23 to which first ends of the contact pins 3 are connected are provided on a backside of the camera module 2 (on a side facing the substrate 1), a plurality of second terminals 11 to which second ends of the contact pins 3 are connected are provided on the substrate 1 (on a surface on which the camera module is mounted).

As such, if the first terminals 23 are provided on the backside of the camera module 2, even when the camera module 2 is connected to the substrate 1 via the contact pins 3, a width of the camera module 2 (a width in a horizontal direction with respect to the surface of the substrate 1 on which the camera module 2 is mounted) does not become wider than its original width. This makes it possible to decrease restrictions on mounting the camera module 2 on the substrate 1.

The contact pins 3 are provided independently such that the contact pins 3 are exposed between the first terminals 23 and the second terminals 11. Moreover, the contact pins 3 are not arranged such that a part of or all the contact pins 3 is/are fixed together as a unit. In other words, in the present embodiment, unlike the arrangement of Patent Document 1, a member for fixing a part of the plurality of contact pins 3 (i.e., a coupler) is not necessary. This makes it possible to provide a mobile phone device with a camera at a low price, and to realize a downsized and thinner mobile phone device with a camera.

Furthermore, the first ends of the contact pins 3 are soldered to ones of the terminals (the first terminals 23 or the second terminals 11), and the second ends of the contact pins 3 have contact with the other ones of the terminals (the first terminals 23 or the second terminals 11), respectively, so that the camera module 2 is electrically connected to the substrate 1. As such, the contact pins 3 are soldered to only ones of the first terminals 23 and the second terminals 11. This means that the contact pins 3 are soldered to one of the camera module 2 and the substrate 1. This allows the camera module 2 to be easily mounted on the substrate 1. In the arrangement, it is also possible to easily replace the camera module 2 or the substrate 1 which is not soldered to the contact pins 3. Here, internal designs of such a mobile phone device with a camera largely differ depending on manufacturers. Further, a position where the camera module 2 is mounted on the substrate 1 is largely different depending on manufactures. In view of these points, in the case where the camera module 2 is connected to the substrate 1 via the contact pins 3, the camera module 2 or the substrate 1 can be easily replaced as such, thereby resulting in that it is possible to satisfy the needs of each manufacturer.

In the present embodiment, the second terminals 11 provided on the substrate 1 are respectively soldered to the contact pins 3 via a solder joint section 12. This makes it possible to respectively form the camera module 2 and the substrate 1 to which the contact pins 3 are soldered, as illustrated in FIG. 3. Since a process of soldering the contact pins 3 to the substrate 1 is easily carried out, it is possible for a manufacturer of the substrate 1 (board maker) to adequately carry out the process. In addition, it is also possible to easily carry out a process of mounting the camera module 2 on the substrate 1 successively to the soldering process. Accordingly, even in a case where a board maker and a manufacturer of the camera module 2 are different, it is possible for the board maker to easily manufacture a mobile phone device with a camera.

Furthermore, in this case, even if a flexible printed circuit board (FPC), which is largely bent because of flexibility, is used as the substrate 1, it is possible to electrically connect the camera module to the FPC via the contact pins 3 with high reliability.

In the present embodiment, the contact pins 3 have elasticity (a spring characteristic). For example, as illustrated in FIG. 3, each of the contact pin 3 is in a wave shape, and has at least one maximum point and at least one minimum point. This arrangement allows the contact pins 3 to absorb an impact on the camera module 2, thereby cushioning the impact.

It is preferable that the contact pins 3 illustrated in FIG. 3 have elastic forces causing the camera module 2 to be away from the substrate 1, that is, elastic forces acting in a direction opposite to a direction in which the camera module 2 is mounted on the substrate 1. This makes it possible that the contact pins 3 surely have contact with the first terminals 23 provided on the camera module 2. Consequently, the camera module 2 can be electrically connected to the substrate 1 with high reliability.

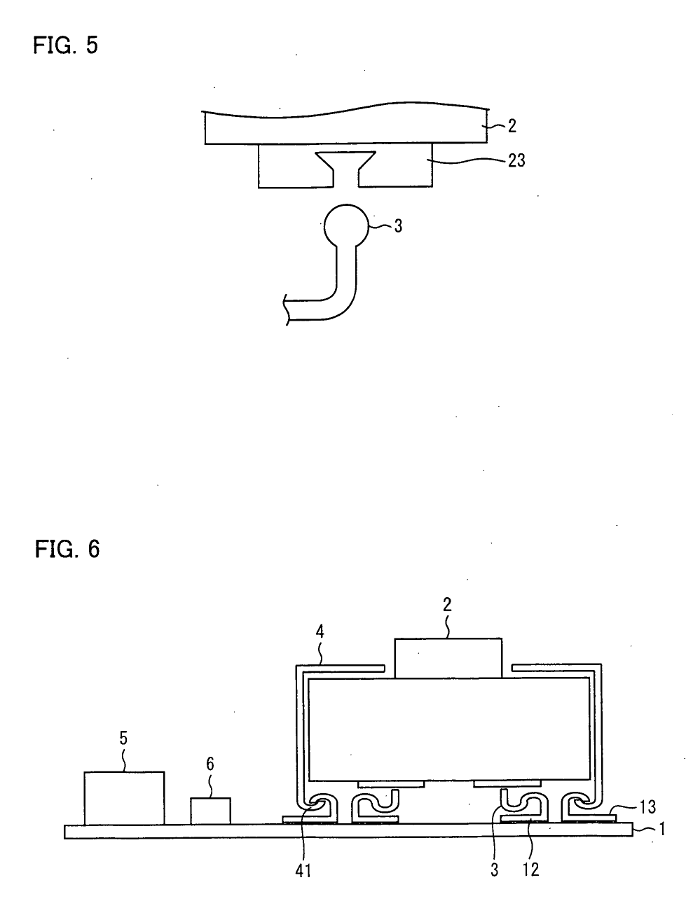

In order that the camera module 2 is connected to the substrate 1 with further higher reliability, it is preferable that the first terminals 23 provided on the camera module 2 engage with one ends of the contact pins 3. FIG. 5 is a cross sectional view illustrating one exemplary arrangement of such an engaging structure. In the exemplary arrangement of FIG. 5, one end of the contact pin 3 that is to be connected to the first terminal 23 is in a spherical shape. On the other hand, the first terminal 23 has a shape that allows the spherical contact pin 3 to engage with the first terminal 23. As such, the contact pins 3 and the first terminals 23 of the camera module 2 have the engaging structure, thereby resulting in that the contact pins 3 can maintain contact with the first terminals 23. This makes it possible to heighten reliability of an electrical connection of the camera module 2 to the substrate 1. Meanwhile, with such the engaging structure, the camera module 2 can be attached to or detached from the substrate 1, so that, even in a case where one of the camera module 2 and the substrate 1 is broken, if the engaged state is released, then it is possible to easily replace the broken camera module 2 or substrate 1.

As has been already described, in the present embodiment, the camera module 2 is placed in the case 4. In order that the reliability of the electrical connection of the camera module 2 to the substrate 1 is further heightened, it is preferable that the case 4 and the substrate 1 be arranged so as to engage with each other. FIG. 6 is a cross sectional view illustrating one exemplary arrangement of such an engaging structure. In the exemplary arrangement of FIG. 6, the substrate 1 includes a latch hook 13 for locking the case 4, and the case 4 includes at its bottom a latch claw 41 that engages with the latch hook 13. In this case, the case 4 pushes the camera module 2 toward the substrate 1. This allows the camera module 2 to be electrically connected to the substrate 1 with higher reliability.

In such the arrangement in which the case 4 is provided, it is possible to change a material constituting the case 4 depending on needs of the camera module 2. For example, in a case where the camera module 2 is required to block electrical waves, the case 4 may be made of a metal or a stainless, or otherwise, the case 4 may be made of a resin that is available at a low price.

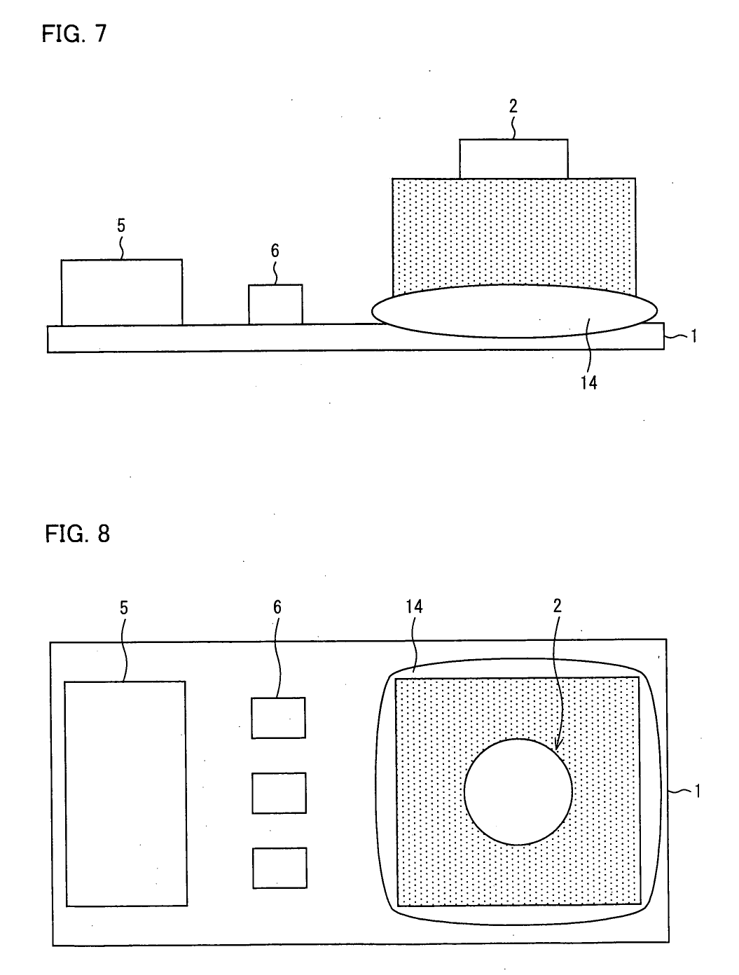

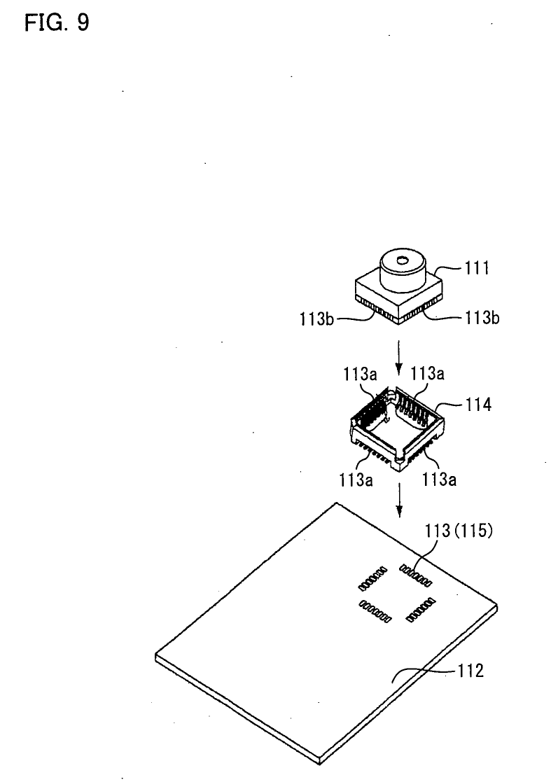

How the substrate 1 is connected (fixed) to the camera module 2 is not limited to the engaging structure of FIG. 5 in which one ends of the contact pins 3 engage with the first terminals 23, and the arrangement of FIG. 6 in which the case 4 pushes the camera module 2 toward the substrate 1. The substrate 1 can be also connected (fixed) to the camera module 2, for example, by an adhesive, as illustrated in FIGS. 7 and 8. FIG. 7 is a cross sectional view illustrating an arrangement in which the camera module 2 is fixed on the substrate 1 by use of an adhesive section 14 instead of the case 4. FIG. 8 is a top view of the arrangement of FIG. 7. In FIGS.7 and 8, an adhesive section 14 is provided in a peripheral region of the camera module 2 so that the camera module 2 is bonded (fixed) to the substrate 1 by the adhesive section 14. This makes it possible to easily fix the camera module 2 at an intended position on the substrate 1. As a result, the camera module 2 can be electrically connected to the substrate 1 with higher reliability. Moreover, in the case where the adhesive section 14 is provided, the case 4 is not necessary, so that a width of the camera module 2 is not required to be further wider than its original width. This allows downsizing of the camera module.

Furthermore, if the adhesive section 14 is made of a UV cure adhesive, then it is possible to mount the camera module 2 on the substrate 1 in such a manner that, while the camera module 2 is pushed toward the substrate 1, the adhesive section 14 is irradiated by UV rays. This makes it possible to obtain an effect equal to that obtained when the camera module 2 is pushed toward the substrate 1 by use of the case 4. It is also possible to provide such an adhesive section in addition to using the case 4 in the arrangement of FIG. 6. As an adhesive, a thermosetting adhesive, which requires less heat for curing (for example, the adhesive which is cured under 90° C.), can be also used.

Here, the camera module 2 is mounted on the substrate 1 in the following way.

Solder is screen-printed onto second terminals 11 provided on a substrate 1. A thickness of the solder is, for example, around 0.12 mm. Contact pins 3 are provided on the second terminals 11 with the use of a mounter device for mounting chip components on the substrate 1. More particularly, a vacuum nozzle of the mounter device (i) holds the contact pins 3 by suction, (ii) conveys the contact pins 3 to the second terminals 11, and (iii) places the contact pins 3 on the second terminals 11. In the similar manner, an electronic component 5 such as a resistor and a capacitor, and a connector 6 are placed on the substrate 1. Then the substrate 1 on which the contact pins 3 and the like are mounted is passed through a reflow oven so that the contact pins 3 and the like are soldered to the substrate 1. At the last, a camera module 2 is fixed on the substrate 1 by use of an adhesive or a case 4.

As described above, a camera device of the present invention includes a plurality of contact pins for connecting a plurality of first terminals provided on a backside of a camera module to a plurality of second terminals provided on a substrate, the contact pins having first and second ends, the first ends being soldered to ones of the first and second terminals and the second ends having contact with the other ones of the first and second terminals, respectively, so that the camera module is electrically connected to the substrate, the contact pins being provided independently. This makes it possible to decrease restrictions on mounting a camera module on a substrate, and to provide a camera device in which a camera module can be easily mounted on a substrate.

In the camera device of the present invention, it is possible that the first ends of the contact pins be soldered to the second terminals.

In the arrangement, the first ends of the contact pins are soldered to the second terminals provided on the substrate. This makes it possible to form respectively a camera module and a substrate to which contact pins are soldered.

Moreover, with the arrangement, even when a substrate is bended, it is possible to surely connect the contact pins to the second terminals. In a case where other members to be soldered are also provided on the substrate, the first ends of the contact pins are soldered to the second terminals at the same time as the other members are mounted on the substrate. In this case, since the camera module is not soldered to the contact pins, it is possible to protect comparatively-heat-sensitive members, provided in the camera module, such as a lens (optical member) and the like from heat generated during soldering.

In the camera device of the present invention, it is preferable that the contact pins have elastic forces causing the camera module to be away from the substrate.

In the arrangement, the contact pins have elastic forces causing the camera module to be away from the substrate, that is, elastic forces acting in a direction opposite to a direction in which the camera module is mounted on the substrate. This makes it possible that the contact pins surely have contact with the first terminals of the camera module. As a result, it is possible to electrically connect a camera module to a substrate with high reliability.

In the camera device of the present invention, it is preferable that the second ends of the contact pins and the first terminals be arranged so as to engage with each other.

In the arrangement, the second ends of the contact pins and the first terminals of the camera module are arranged so as to engage with each other. This makes it possible that the contact pins maintain contact with the first terminals. As a result, it is possible to heighten reliability of an electrical connection of a camera module to a substrate. Moreover, such an engaging structure allows a camera module to be attached to or detached from a substrate, so that, even when one of the camera module and the substrate is broken, if the engaged state is released, the broken camera module or substrate can be easily replaced.

It is preferable that the camera device of the present invention include a fixing section for fixing the camera module on the substrate.

In the arrangement, the camera device includes a fixing section for fixing the camera module on the substrate. With the arrangement, the fixing section holds the camera module fixed in place. This makes it possible to electrically connect a camera module to a substrate with high reliability.

In the camera device of the present invention, the fixing section may be an adhesive section for bonding the camera module to the substrate.

In the arrangement, the fixing section is an adhesive section for bonding the camera module to the substrate, thereby resulting in that the camera module can be easily fixed on the substrate. This makes it possible to electrically connect a camera module to a substrate with higher reliability.

In the camera device of the present invention, the fixing section may be a case in which the camera module is place, and which pushes the camera module toward the substrate.

In the arrangement, the camera module is placed in a case provided as the fixing section. This allows the camera module to be protected by the case. In addition, the case is arranged so as to push the camera module toward the substrate. Accordingly, this makes it possible to electrically connect a camera module to a substrate with higher reliability.

In the camera device of the present invention, the substrate may be a flexible printed circuit board.

In the arrangement, the camera module is mounted on a flexible printed circuit board (FPC). Even if the FPC is largely bended due to its flexibility, with the arrangement, it is possible to electrically connect the camera module to the FPC with high reliability by use of the contact pins.

According to the present invention, the first ends of the contact pins are soldered to ones of the first and second terminals, and the second ends of the contact pins have contact with the other ones of the first terminals and second terminals, instead of being soldered thereto, so that the camera module is electrically connected to the substrate. Therefore, a coupler for connection is not necessary. This allows a manufacturer of a camera device such as a mobile phone with a camera or a portable information device to mount a camera module on a substrate.

The present invention is not limited to the description of the embodiments above, but may be altered by a skilled person within the scope of the claims. An embodiment based on a proper combination of technical means disclosed in different embodiments is encompassed in the technical scope of the present invention.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A camera device in which a camera module is mounted on a substrate, comprising:
a plurality of contact pins for connecting a plurality of first terminals provided on a backside of the camera module to a plurality of second terminals provided on the substrate, respectively,
the contact pins having first and second ends,
the first ends being soldered to ones of the first and second terminals and the second ends having contact with the other ones of the first and second terminals, respectively, so that the camera module is electrically connected to the substrate, and
the contact pins being provided independently.

2. The camera device as set forth in claim 1, wherein:
the first ends of the contact pins are soldered to the second terminals.

3. The camera device as set forth in claim 2, wherein:
the contact pins have elastic forces causing the camera module to be away from the substrate.

4. The camera device as set forth in claim 2, wherein:
the second ends of the contact pins and the first terminals are arranged so as to engage with each other.

5. The camera device as set forth in claim 1, further comprising a fixing section for fixing the camera module on the substrate.

6. The camera device as set forth in claim 5, wherein:
the fixing section is an adhesive section for bonding the camera module to the substrate.

7. The camera device as set forth in claim 5, wherein:
the fixing section is a case in which the camera module is placed, and which pushes the camera module toward the substrate.

8. The camera device as set forth in claim 2, wherein:
the substrate is a flexible printed circuit board.

9. The camera device as set forth in claim 6, wherein:
the adhesive section is made of a UV cure adhesive.

10. An electronic device comprising a camera device,
in said camera device a camera module being mounted on a substrate,
said camera device including:
a plurality of contact pins for connecting a plurality of first terminals provided on a backside of the camera module to a plurality of second terminals provided on the substrate, respectively,
the contact pins having first and second ends,
the first ends being soldered to ones of the first and second terminals and the second ends having contact with the other ones of the first and second terminals, respectively, so that the camera module is electrically connected to the substrate, and
the contact pins being provided independently.
